(19) United States
(12) Patent Application Publication
(10) Pub. No.: US 2013/0214645 A1
(43) Pub. Date: Aug. 22, 2013

(54) PIEZOELECTRIC DEVICE AND METHOD FOR FABRICATING THE SAME

(71) Applicant: Nihon Dempa Kogyo Co., Ltd., (US)

(72) Inventor: SHUICHI MIZUSAWA, SAITAMA (JP)

(73) Assignee: NIHON DEMPA KOGYO CO., LTD., TOKYO (JP)

(21) Appl. No.: 13/771,095

(22) Filed: Feb. 20, 2013

(30) Foreign Application Priority Data
Feb. 22, 2012 (JP) 2012-035974

(51) Int. Cl. H01L 41/053; H01L 41/29

(52) U.S. Cl. CPC H01L 41/053; H01L 41/29
USPC 310/344; 29/25.35

(57) ABSTRACT

A surface mount type piezoelectric device includes a piezoelectric vibrating piece, a base plate in a rectangular shape, and a lid plate. The piezoelectric vibrating piece includes a vibrator vibrating at a predetermined vibration frequency. The base plate has one principal surface where the piezoelectric vibrating piece being to be placed. The lid plate seals the vibrator. The other principal surface of the base plate includes a pair of mounting terminals to mount the piezoelectric device. The pair of mounting terminals includes a metal film and an electroless plating film. The electroless plating film is formed on a surface of the metal film. The mounting terminal includes a trace from which a part of the electroless plating film is removed by laser or dicing.

### CROSS REFERENCE TO RELATED APPLICATIONS

This application claims the priority benefit of Japan application serial no. 2012-035974, filed on Feb. 22, 2012. The entirety of the above-mentioned patent application is hereby incorporated by reference herein and made a part of this specification.

### TECHNICAL FIELD

This disclosure relates to a piezoelectric device that includes an electrode formed by an electroless plating, and a method for fabricating the piezoelectric device.

### DESCRIPTION OF THE RELATED ART

A surface mount type piezoelectric device that includes a piezoelectric vibrating piece, which vibrates at a predetermined vibration frequency, is known. A mounting terminal is formed on a surface of the piezoelectric device as an electrode. The piezoelectric device is mounted to a printed circuit board or similar member via this mounting terminal. Since the mounting terminal is formed on the surface of the piezoelectric device, the mounting terminal may be detached by heating of a solder or similar cause or may be damaged. Therefore, with the piezoelectric device, a thick film is formed on the mounting terminal by plating or similar method to ensure conduction. Additionally, the thick film formed by plating is also formed as a barrier layer that prevents the solder from absorbing a metal of the mounting terminal.

For example, Japanese Unexamined Patent Application Publication No. 2000-252375 discloses a mounting terminal formed with a conductive paste and a plating layer formed on a surface of the conductive paste.

However, since the plating layer is formed thick, the plating layer may apply stress to the piezoelectric device. The stress applied to the piezoelectric device warps the piezoelectric device, which causes a problem of detachment of the plating layer or the mounting terminal including the plating layer. Especially, this detachment occurs in a fabrication of the piezoelectric device, which employs a method where a plurality of piezoelectric devices is formed on a wafer, and then the wafer is diced to form individual piezoelectric devices. This is because that stress applied to the piezoelectric device changes at dicing of the wafer, thus increasing distortion of the piezoelectric device.

A need thus exists for a piezoelectric device which is not susceptible to the drawback mentioned above.

### SUMMARY

A surface mount type piezoelectric device according to a first aspect includes a piezoelectric vibrating piece, a base plate in a rectangular shape, and a lid plate. The piezoelectric vibrating piece includes a vibrator vibrating at a predetermined vibration frequency. The base plate has one principal surface where the piezoelectric vibrating piece is to be placed. The lid plate seals the vibrator. The other principal surface of the base plate includes a pair of mounting terminals to mount the piezoelectric device. The pair of mounting terminals includes a metal film and an electroless plating film. The electroless plating film is formed on a surface of the metal film. The mounting terminal includes a trace from which a part of the electroless plating film is removed by laser or dicing.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view of a piezoelectric device 100;

FIG. 2A is a cross-sectional view taken along the line IIA-IIA of FIG. 1;

FIG. 2B is an enlarged view of the portion enclosed by a dotted line 161 of FIG. 2A;

FIG. 3A is a plan view of the surface at the +Y′-axis side of a base plate 120;

FIG. 3B is a plan view of the surface at the −Y′-axis side of the base plate 120;

FIG. 4 is a flowchart illustrating a method for fabricating the piezoelectric device 100;

FIG. 5A is a plan view of the surface at the +Y′-axis side of a base wafer W120;

FIG. 5B is a plan view of the surface at the −Y′-axis side of the base wafer W120;

FIG. 6 is a plan view of the surface at the +Y′-axis side of a lid wafer W110;

FIG. 7A is a partial cross-sectional view of the base wafer W120 where a piezoelectric vibrating piece 130 is placed;

FIG. 7B is a partial cross-sectional view of the lid wafer W110, the piezoelectric vibrating piece 130, and the base wafer W120;

FIG. 7C is a partial cross-sectional view of the lid wafer W110, the piezoelectric vibrating piece 130, and the base wafer W120 where an electroless plating film 153 is formed;

FIG. 8 is a graph illustrating a relationship between a thickness TN of a nickel (Ni) layer of the electroless plating film 153 and a detachment rate of the electroless plating film 153;

FIG. 9A is a partial plan view of a surface at the −Y′-axis side of the base wafer W120 where the electroless plating film 153 is formed;

FIG. 9B is a partial plan view of the surface at the −Y′-axis side of the base wafer W120 from which a part of the electroless plating film 153 is removed;

FIG. 9C is an enlarged plan view of the portion enclosed by a dotted line 162 of FIG. 9B;

FIG. 9D is an enlarged plan view of the surface at the −Y′-axis side of a base wafer W120a;

FIG. 10A is a partial plan view of the surface at the −Y′-axis side of a base wafer W120b before the electroless plating film 153 is removed;

FIG. 10B is a partial plan view of the surface at the −Y′-axis side of the base wafer W120b after the electroless plating film 153 is removed;

FIG. 10C is an enlarged plan view of the portion enclosed by a dotted line 163 of FIG. 10B;

FIG. 11 is an exploded perspective view of a piezoelectric device 200;

FIG. 12A is a cross-sectional view taken along the line XIVA-XIVA of FIG. 11;

FIG. 12B is an enlarged view of the portion enclosed by a dotted line 164 of FIG. 12A;

FIG. 13 is a flowchart illustrating a method for fabricating the piezoelectric device 200;

FIG. 14A is a partial cross-sectional view of a piezoelectric wafer W230, the lid wafer W110, and a base wafer W220;

FIG. 14B is a partial cross-sectional view of the piezoelectric wafer W230, the lid wafer W110, and the base wafer W220 where a second metal film 152 is formed; and

FIG. 14C is a partial cross-sectional view of the piezoelectric wafer W230, the lid wafer W110, and the base wafer W220 where the electroless plating film 153 is formed.

### DETAILED DESCRIPTION

The preferred embodiments of this disclosure will be described with reference to the attached drawings. It will be understood that the scope of the disclosure is not limited to the described embodiments, unless otherwise stated.

### Constitution of a Piezoelectric Device 100 According to a First Embodiment

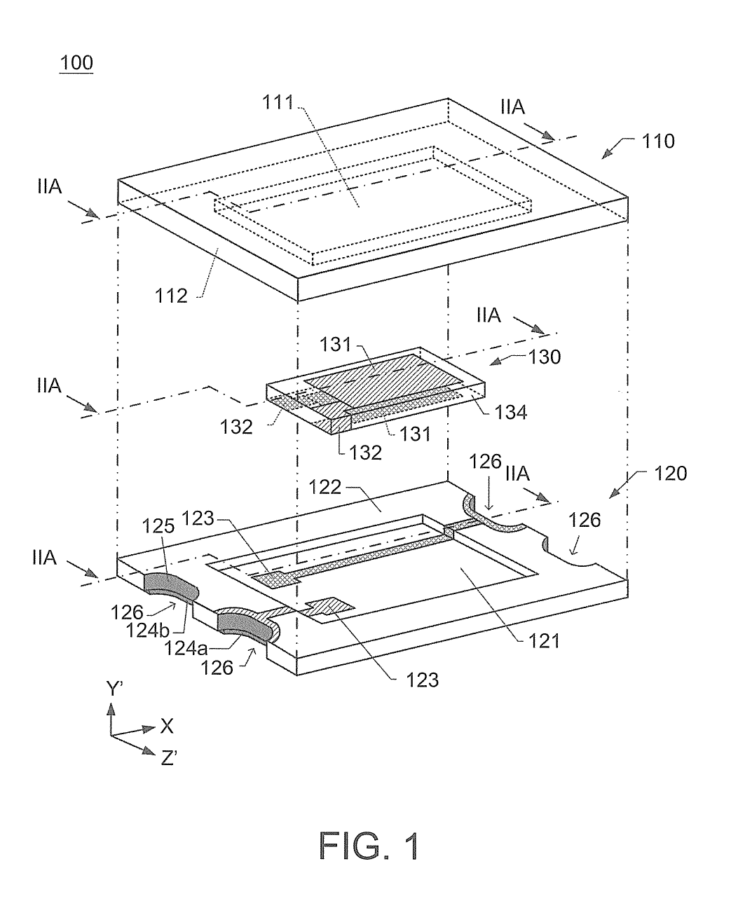

FIG. 1 is an exploded perspective view of the piezoelectric device 100. The piezoelectric device 100 includes a lid plate 110, a base plate 120, and a piezoelectric vibrating piece 130. An AT-cut quartz-crystal vibrating piece, for example, is employed for the piezoelectric vibrating piece 130. The AT-cut quartz-crystal vibrating piece has a principal surface (in the Y-Z plane) that is tilted by 35° 15′ about the Y-axis of crystallographic axes (XYZ) in the direction from the Z-axis to the Y-axis around the X-axis. In the following description, the new axes tilted with reference to the axis directions of the AT-cut quartz-crystal vibrating piece are denoted as the Y′-axis and the Z′-axis. This disclosure defines the long side direction of the piezoelectric device 100 as the X-axis direction, the height direction of the piezoelectric device 100 as the Y′-axis direction, and the direction perpendicular o the X and Y′-axis directions as the Z′-axis direction.

The piezoelectric vibrating piece 130 includes a vibrator 134, an excitation electrode 131, and an extraction electrode 132. The vibrator 134 vibrates at a predetermined vibration frequency and has a rectangular shape. The excitation electrodes 131 are formed on surfaces at the +Y′-axis side and the −Y′-axis side of the vibrator 134. The extraction electrode 132 is extracted from each excitation electrode 131 to the −X-axis side. The extraction electrode 132 is extracted from the excitation electrode 131, which is formed on the surface at the +Y′-axis side of the vibrator 134. The extraction electrode 132 is extracted from the excitation electrode 131 to the −X-axis side, and is further extracted to the surface at the −Y′-axis side of the vibrator 134 via the side surface at the +Z′-axis side of the vibrator 134. The extraction electrode 132 is extracted from the excitation electrode 131, which is formed on the surface at the −Y′-axis side of the vibrator 134. The extraction electrode 132 is extracted from the excitation electrode 131 to the −X-axis side, and is formed up to the corner at the −X-axis side and the −Z′-axis side of the vibrator 134.

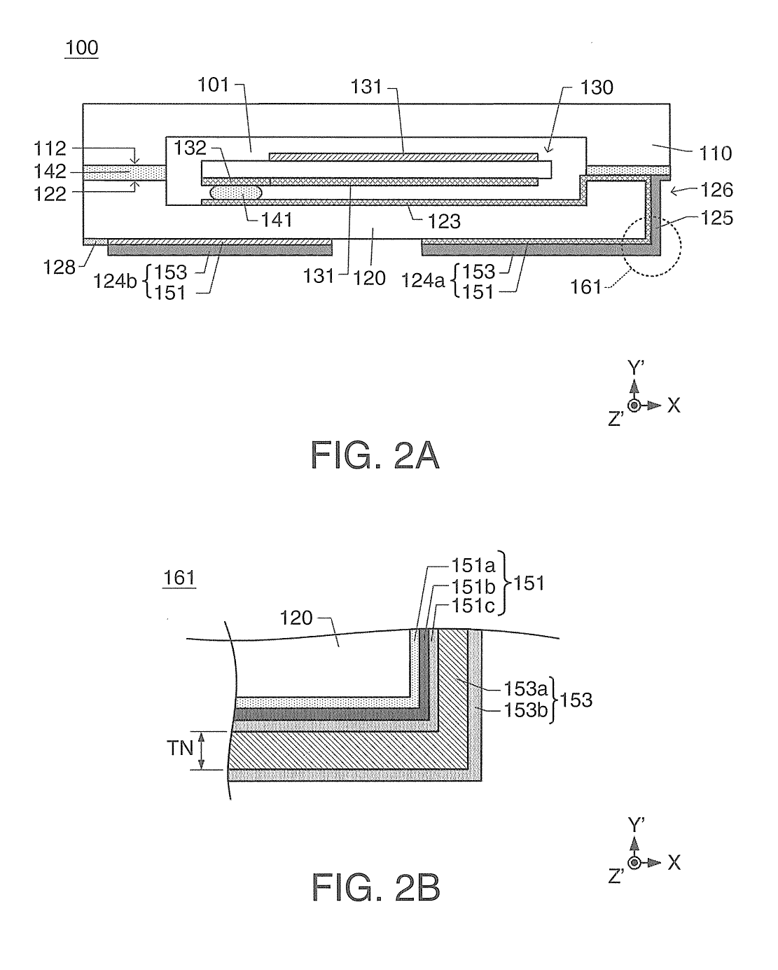

The base plate 120 employs a material such as a crystal and a glass as a base material. An electrode is formed on a surface of this base material. A bonding surface 122 is formed at the peripheral area of the surface at the +Y′-axis side of the base plate 120. The bonding surface 122 is to be bonded to the lid plate 110 via a sealing material 142 (see FIG. 2A). The base plate 120 includes a depressed portion 121 at the center of the surface at the +Y′-axis side. The depressed portion 121 is depressed from the bonding surface 122 in the −Y′-axis direction. The depressed portion 121 includes a pair of connecting electrodes 123. Each connecting electrode 123 electrically connects to an extraction electrode 132 of the piezoelectric vibrating piece 130 via a conductive adhesive 141 (see FIG. 2A). The base plate 120 includes a mounting terminal on the surface at the −Y′-axis side. The mounting terminal mounts the piezoelectric device 100 to a printed circuit board or similar member. In the base plate 120, the mounting terminal includes a hot terminal 124a and a grounding terminal 124b. The hot terminal 124a and the grounding terminal 124b are terminals that are electrically connected to an external power supply or similar component to apply a voltage to the piezoelectric device 100. Castellations 126 are formed at the +Z′-axis side and the −Z′-axis side on side surfaces at the +X-axis side and the −X-axis side of the base plate 120. The castellation 126 is depressed toward inside of the base plate 120. A side surface electrode 125 is formed at the side surface of the castellation 126. The hot terminal 124a electrically connects to the connecting electrode 123 via the side surface electrode 125.

The lid plate 110 includes a depressed portion 111 on the surface at the −Y′-axis side. The depressed portion 111 is depressed in the +Y-axis direction. A bonding surface 112 is formed surrounding the depressed portion 111. The bonding surface 112 is bonded to the bonding surface 122 of the base plate 120 via the sealing material 142 (see FIG. 2A).

FIG. 2A is a cross-sectional view taken along the line IIA-IIA of FIG. 1. A sealed cavity 101 is formed in the piezoelectric device 100 by bonding the bonding surface 122 of the base plate 120 and the bonding surface 112 of the lid plate 110 together via the sealing material 142. The cavity 101 houses the piezoelectric vibrating piece 130. The extraction electrode 132 electrically connects to the connecting electrode 123 of the base plate 120 via the conductive adhesive 141. This electrically connects the excitation electrode 131 to the hot terminal 124a. Further, the hot terminal 124a, the grounding terminal 124b, and the side surface electrode 125, which is formed at the castellation 126, are formed by a first metal film 151 and an electroless plating film 153. The first metal film 151 is formed on the surface at the −Y′-axis side of the base material of the base plate 120. The electroless plating film 153 is formed on the surface of the first metal film 151. A trace 128 remains after the electroless plating film 153 is removed. The trace 128 is at a region where the hot terminal 124a and the grounding terminal 124b are in contact with the side at the −X-axis side or the +X-axis side of the base plate 120.

FIG. 2B is an enlarged view of the portion enclosed by a dotted line 161 of FIG. 2A. FIG. 2B illustrates an enlarged cross-sectional view of the hot terminal 124a. FIG. 2B illustrates a constitution of the hot terminal 124a. The constitution of the grounding terminal 124b is similar to the constitution of the hot terminal 124a. The first metal film 151 is formed of three layers: a first layer 151a, a second layer 151b, and a third layer 151c. The first layer 151a is a layer made of a chrome (Cr) and is formed on a surface of the base material of the base plate 120. The chrome (Cr) is employed as a material of the first layer 151a for good adhesion to a material such as a crystal and a glass, which is the base material of the base plate 120. The third layer 151c, which is formed on a surface of the first metal film 151, is made of a gold (Au). A chrome (Cr) adheres well to a material such as a crystal and a glass, but does not stick to solder or similar material. Accordingly, the surface of the first metal film 151 is covered with a gold (Au), which sticks to a solder or similar material well. Further, in the first metal film 151, the second layer 151b is formed between the first layer 151a and the third layer 151c. When heat or the like is applied to the chrome (Cr), which constitutes the first layer 151a, during a fabrication process, the chrome diffuses to another layer. This reduces adhesion between the chrome (Cr) and the base plate 120. Further, when the chrome (Cr) diffuses to a surface of the first metal film 151, the chrome (Cr) oxidizes, making formation of the electroless plating film 153 or similar member difficult. To prevent this spread of the chrome (Cr), the second layer 151b is disposed. This prevents the chrome (Cr) from diffusing to the gold (Au) layer.

The second layer 151b is made of, for example, a nickel tungsten (Ni—W). The second layer 151b may be made of platinum (Pt). For example, when platinum (Pt) is employed, the first layer 151a is formed to have a thickness of 300 angstroms (Å) to 500 angstroms, the second layer 151b is formed to have a thickness of 1000 angstroms to 2000 angstroms, and the third layer 151c is formed to have a thickness of 1000 angstroms to 2000 angstroms. An electrode that includes the electroless plating film 153 is, when compared with an electrode that does not include the electroless plating film 153, likely to cause detachment due to distortion of the base plate 120 by stress generated by the electroless plating film 153. In the first metal film 151, formation of the second layer 151b prevents spread of the chrome (Cr), thus holding strong adhesion between the first metal film 151 and the base material of the base plate 120. This prevents detachment of the first metal film 151.

The electroless plating film 153 is formed of a first layer 153a and a second layer 153b. The first layer 153a is formed on a surface of the first metal film 151. The second layer 153b is formed on a surface of the first layer 153a. The first layer 153a is a nickel (Ni) layer and has the thickness TN of 1 μm to 3 μm. To ensure connection of the hot terminal 124a and a solder or similar material, the second layer 153b made of a gold (Au) is formed on a surface of the first layer 153a.

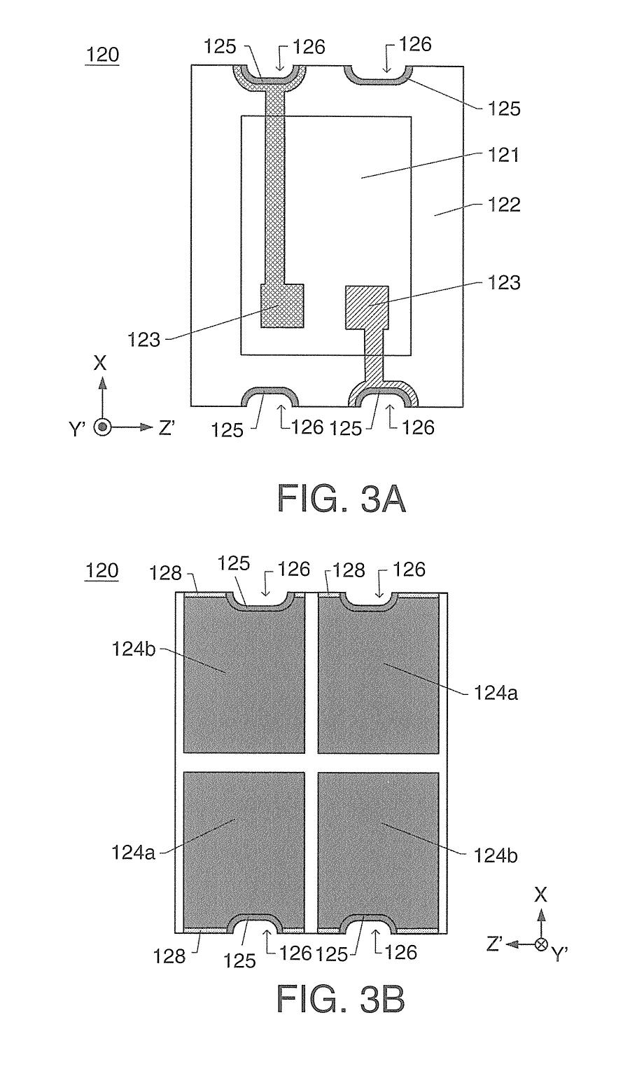

FIG. 3A is a plan view of the surface at the +Y′-axis side of the base plate 120. The bonding surface 122 is formed at the peripheral area of the surface at the +Y′-axis side of the base plate 120. The base plate 120 includes a depressed portion 121 at the center of the surface at the +Y′-axis side. The depressed portion 121 is depressed from the bonding surface 122 in the −Y′-axis direction. Castellations 126 are formed at the +Z′-axis side and the −Z′-axis side on side surfaces at the +X-axis side and the −X-axis side of the base plate 120. The castellation 126 is depressed inside of the base plate 120. The depressed portion 121 of the base plate 120 includes a pair of connecting electrodes 123. Each connecting electrode 123 electrically connects to each side surface electrode 125 that are formed at the castellations 126 at the +X-axis side and the −Z′-axis side and at the −X-axis side and the +Z′-axis side.

FIG. 3B is a plan view of the surface at the −Y′-axis side of the base plate 120. The hot terminal 124a and the grounding terminal 124b are formed on the surface at the −Y′-axis side of the base plate 120. The hot terminals 124a are formed at the +X-axis side and the −Z′-axis side and at the −X-axis side and the +Z′-axis side. The grounding terminals 124b are formed at the +X-axis side and the +Z′-axis side and at the −X-axis side and the −Z′-axis side. The hot terminal 124a electrically connects to the connecting electrode 123 via the side surface electrode 125 formed at the castellation 126. Traces 128 remain after the electroless plating film 153 is removed at regions where the hot terminals 124a and the grounding terminals 124b are in contact with the sides at the +X-axis side and the −X-axis side of the base plate 120.

### Fabrication Method of the Piezoelectric Device 100

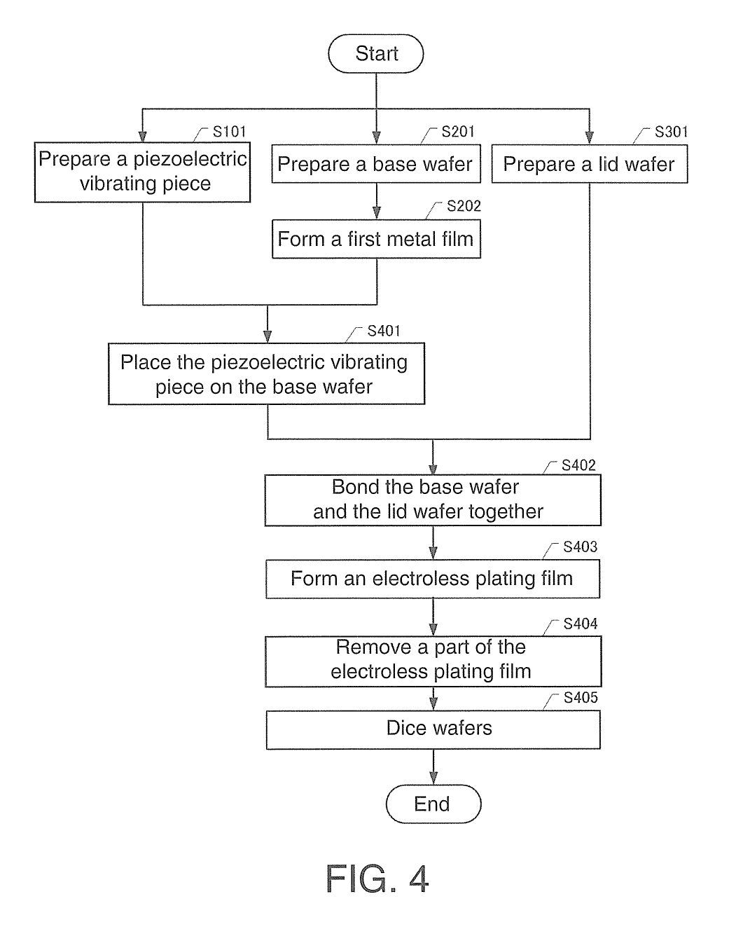

FIG. 4 is a flowchart illustrating a method for fabricating the piezoelectric device 100. A description will be given of the method for fabricating the piezoelectric device 100 following the flowchart of FIG. 4.

In step S101, a plurality of piezoelectric vibrating pieces 130 is prepared. Step S101 is a process for preparing a piezoelectric vibrating piece. In step S101, first, an outline of a plurality of piezoelectric vibrating pieces 130 is formed on a piezoelectric wafer, which is made of a piezoelectric material, by etching or similar method. Further, the excitation electrode 131 and the extraction electrode 132 are formed on each piezoelectric vibrating piece 130 by a method such as sputtering or vacuum evaporation. The plurality of piezoelectric vibrating pieces 130 is prepared by folding and removing the piezoelectric vibrating piece 130 from the piezoelectric wafer.

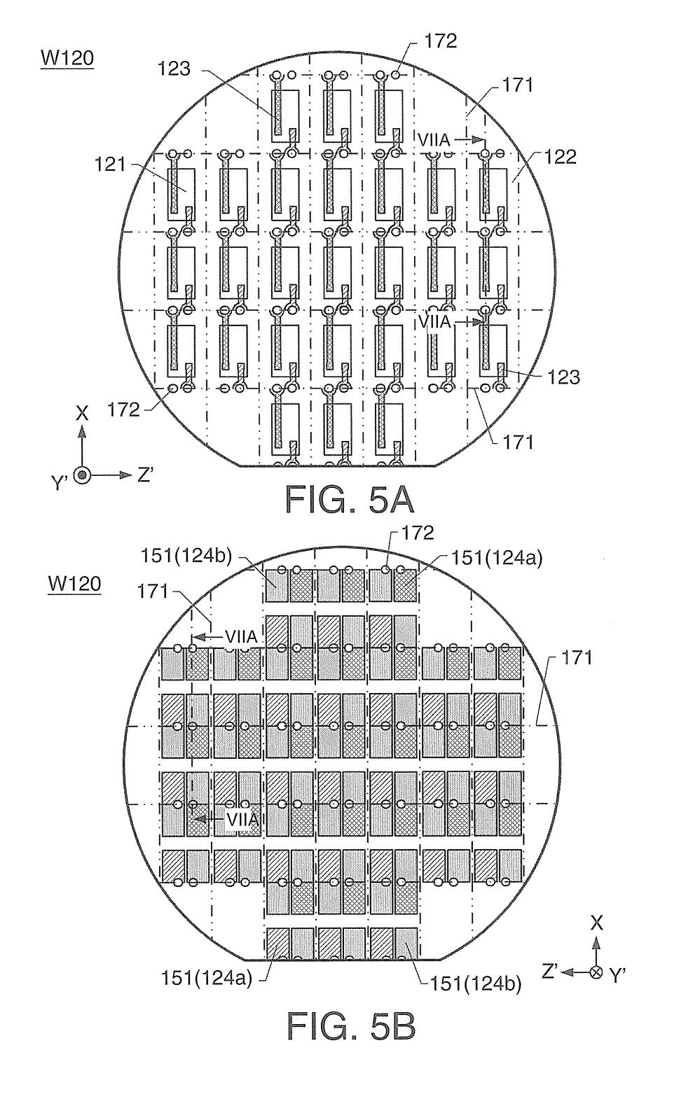

In step S201, the base wafer W120 is prepared. Step S201 is a process for preparing a base wafer. A plurality of base plates 120 is formed on the base wafer W120. The base wafer W120 employs a material such as a crystal or a glass as the base material. In the base wafer W120, the depressed portion 121 and a through hole 172 (see FIG. 5A), which becomes the castellation 126 by dicing the wafer, are formed by etching.

In step S202, the first metal film 151 is formed on the base wafer W120. Step S202 is a process for forming a first metal film. The first metal film 151, which is formed on the base wafer W120, is formed of, for example, the first layer 151a, the second layer 151b, and the third layer 151c as illustrated in FIG. 2B. A chrome (Cr) constitutes the first layer 151a, a nickel tungsten (Ni—W) constitutes the second layer 151b, and a gold (Au) constitutes the third layer 151c. These layers are formed by sputtering or vacuum evaporation. In step S202, formation of the first metal film 151 forms the connecting electrode 123, a part of the side surface electrode 125, a part of the hot terminal 124a, and a part of the wounding terminal 124b on each base plate 120.

FIG. 5A is a plan view of the surface at the +Y′-axis side of the base wafer W120. A plurality of base plates 120 is formed on the base wafer W120. Each base plate 120 is aligned in the X-axis direction and the Z′-axis direction. In FIG. 5A, a scribe line 171 is illustrated at a boundary between the base plates 120 adjacent one another. The scribe line 171 is a line that indicates a position at which the wafer is diced in step S405, which will be described below. The through hole 172 is formed on the scribe line 171 that extends in the X-axis direction. The through hole 172 passes through the base wafer W120 in the Y′-axis direction. After the wafer is diced in step S405, which will be described below, the through hole 172 becomes the castellations 126. The depressed portion 121 is formed on the surface at the +Y′-axis side of each base plate 120. The connecting electrode 123, which is formed of the first metal film 151, is formed on the surface at the +Y′-axis side of each base plate 120.

FIG. 5B is a plan view of the surface at the −Y′-axis side of the base wafer W120. The first metal film 151 is formed on the surface at the −Y′-axis side of the base wafer W120. The first metal film 151 is to be a part of the hot terminal 124a and a part of the grounding terminal 124b. The first metal film 151, which constitutes the hot terminal 124a and the grounding terminal 124b, electrically connects to the connecting electrode 123 via the side surface electrode 125 formed at the through hole 172. The side surface electrode 125, which is formed at one through hole 172, connects to one hot terminal 124a and one grounding terminal 124b.

Returning to FIG. 4, in step S301, the lid wafer W110 is prepared. Step S301 is a process for preparing the lid wafer W110. A plurality of lid plates 110 is formed on the lid wafer W110. The depressed portion 111 is formed on the surface at the −Y′-axis side of each lid plate 110.

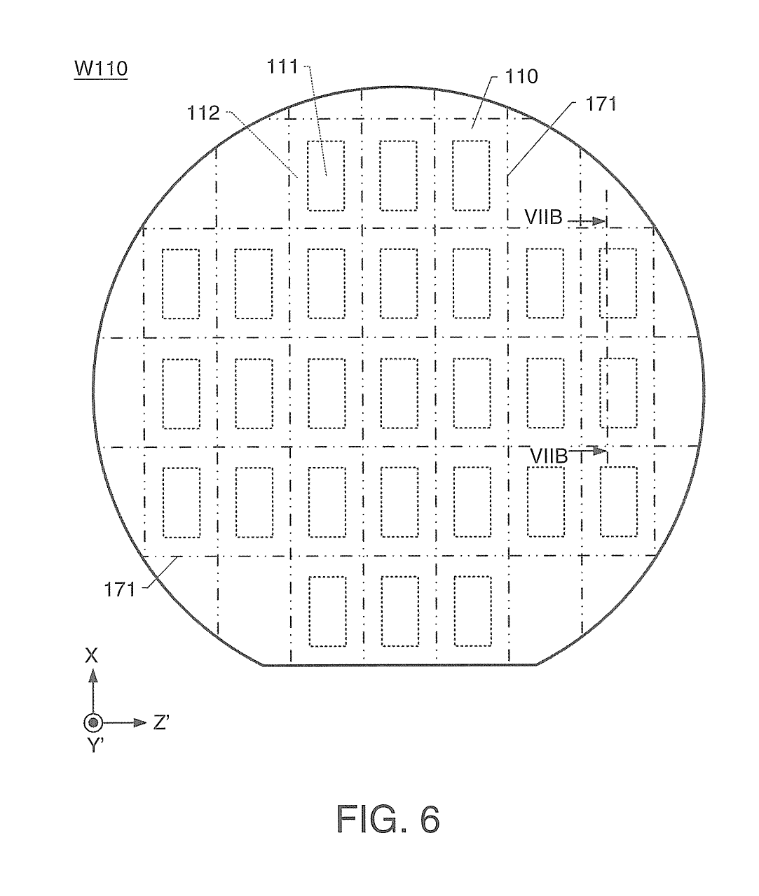

FIG. 6 is a plan view of the surface at the +Y′-axis side of the lid wafer W110. A plurality of lid plates 110 is formed on the lid wafer W110. The depressed portion 111 and the bonding surface 112 are formed on the surface at the −Y′-axis side of each lid plate 110. In FIG. 6, a two-dot chain line is drawn between the lid plates 110 adjacent one another. This two-dot chain line is the scribe line 171.

In step S401, the piezoelectric vibrating piece 130 is placed on the base wafer W120. Step S401 is a placement process. The piezoelectric vibrating piece 130 is placed on each depressed portion 121 on the base wafer W 120 with the conductive adhesive 141.

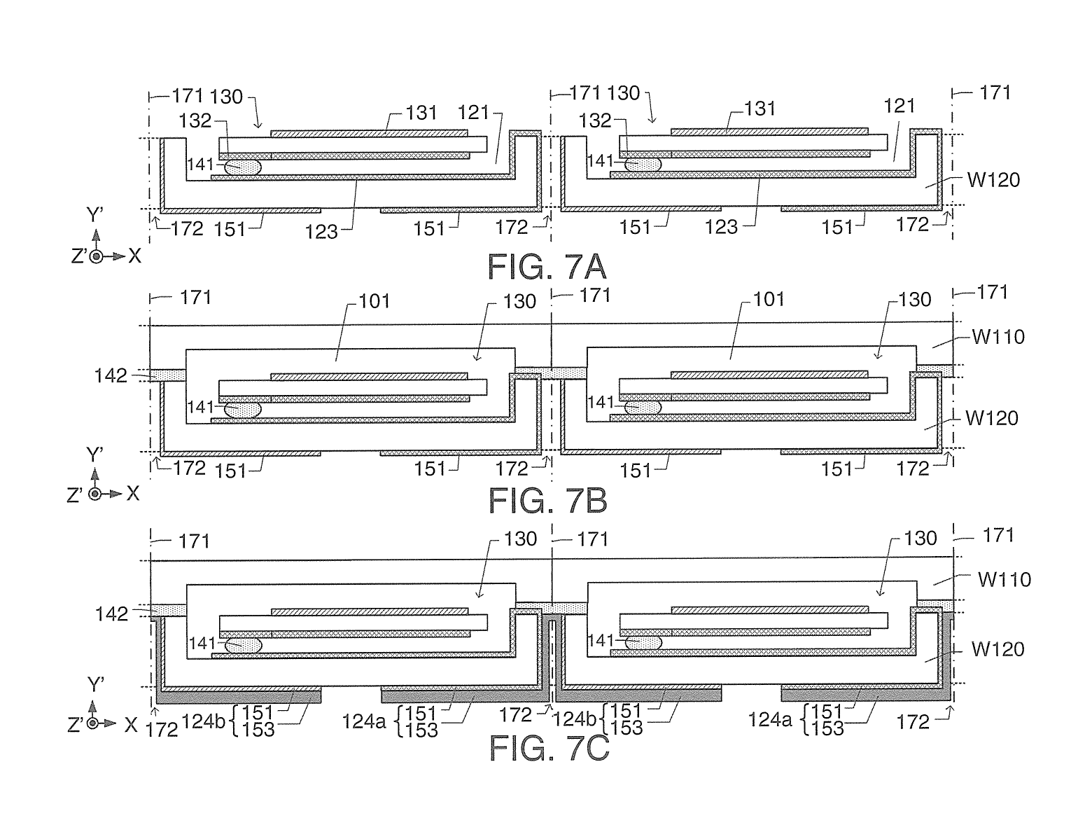

FIG. 7A is a partial cross-sectional view of the base wafer W120 where the piezoelectric vibrating piece 130 is placed. FIG. 7A illustrates a cross-sectional view including a cross section taken along the line VIIA-VIIA of FIGS. 5A and 5B. The extraction electrode 132 and the connecting electrode 123 are electrically connected together via the conductive adhesive 141 Thus, the piezoelectric vibrating piece 130 is placed on the depressed portion 121 of the base wafer W120. This electrically connects the excitation electrode 131 and the first metal film 151, which is formed on the surface at the −Y′-axis side of the base wafer W120.

In step S402, the base wafer W120 and the lid wafer W110 are bonded together. Step S402 is a bonding process. The base wafer W120 and the lid wafer W110 are bonded as follows. The sealing material 142 (see FIG. 2A) is applied to the bonding surface 122 of the base wafer W120 or the bonding surface 112 of the lid wafer W110. Then, the bonding surface 122 of the base wafer W120 and the bonding surface 112 of the lid wafer W110 are bonded such that they face each other while sandwiching the sealing material 142.

FIG. 7B is a partial cross-sectional view of the lid wafer W110, the piezoelectric vibrating piece 130, and the base wafer W120. FIG. 7B illustrates a cross-sectional view including a cross section taken along the line VIIA-VIIA of FIGS. 5A and 5B and the line VIIB-VIIB of FIG. 6. The lid wafer W110 and the base wafer W120 are bonded together via the sealing material 142. Thus, the sealed cavity 101 is formed. The piezoelectric vibrating piece 130 is placed on the cavity 101.

In step S403, the electroless plating film 153 is formed. Step S403 is a process of electroless plating. In step S403, the electroless plating films 153 are formed by performing electroless plating on the surfaces of the first metal films 151, which are formed on the surface of the base wafer W120 at the −Y′-axis side. The electroless plating film 153 is formed on the surface at the −Y′-axis side of the base wafer W120 and a side surface of the through hole 172.

FIG. 7C is a partial cross-sectional view of the lid wafer W110, the piezoelectric vibrating piece 130, and the base wafer W120 where the electroless plating film 153 is formed. FIG. 7C illustrates a cross-sectional view of the cross section similarity to FIG. 7B. First, the electroless plating film 153 is formed as illustrated in FIG. 2B. A thick film of a nickel (Ni) is formed on a surface of the first metal film 151 by electroless plating so as to form the first layer 153a. Further, an electroless plating is performed with a gold (Au) on the surface of the first layer 153a, thus the second layer 153b is formed.

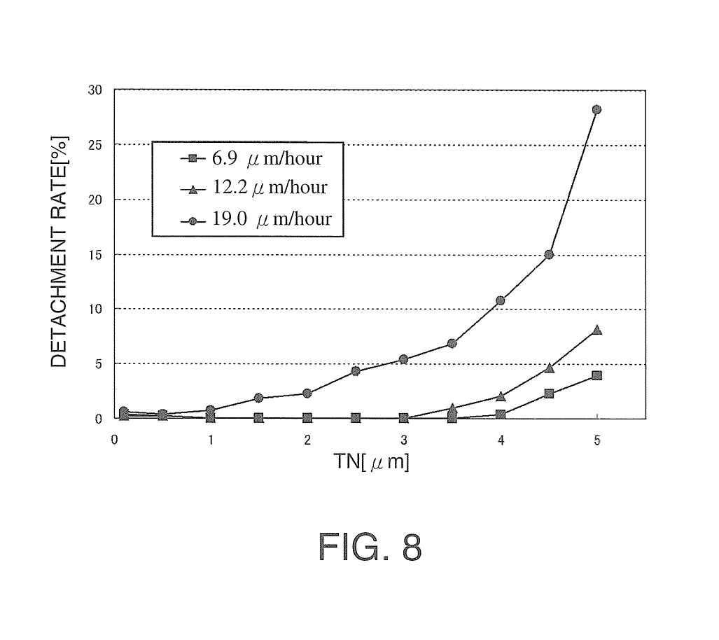

FIG. 8 is a graph illustrating a relationship between the thickness TN of a nickel (Ni) layer of the electroless plating film 153 and a detachment rate of the electroless plating film 153. FIG. 8 illustrates results in the case where the nickel (Ni) layer of the electroless plating film 153 is formed at three speeds: 6.9 μm/hour, 12.2 μm/hour, and 19.0 μm/hour. In the graph, the black square indicates a formation speed of 6.9 μm/hour, the black triangle indicates a formation speed of 12.2 μm/hour, and the black circle indicates a formation speed of 19.0 μm/hour. The formation speed can be adjusted, for example, by a temperature condition. The following is assumed. When the formation speed is 6.9 μm/hour, the temperature is 45° C. to 55° C. When the formation speed is 12.2 μm/hour, the temperature is 60° C. to 70° C. When the formation speed is 19.0 μm/hour, the temperature is 70° C. to 80° C. The detachment rate is obtained by performing the following methods. A scratch test confirms whether the metal film detaches or not by scratching a surface of the metal film with a metal needle or a diamond stylus. A tape peeling test confirms whether the metal film detaches or not by peeling a tape pasted on the metal film. The detachment rate in FIG. 8 indicates a rate of the number of individuals from which the metal film is detached relative to the number of individuals that are target for the tests.

In the case where the formation speeds are 6.9 μm/hour and 12.2 μm/hour, the detachment rate exists but is small when the thickness TN of the nickel layer is 0.1 μm to 1 μm. This is possibly because when the thickness TN of the nickel layer is thin, the nickel layer is not completely secured to the surface of the metal film. In the case where the formation speed is 6.9 μm/hour, the detachment rate is 0% at the thickness TN of between 1 μm to 3.5 μm and increases when the thickness TN becomes equal to or more than 3.5 μm. In the case where the formation speed is 12.2 μm/hour, the detachment rate is 0% at the thickness TN of between 1 μm to 3 μm and increases when the thickness TN becomes equal to or more than 3 μm. In the case where the formation speed is 19.0 μm/hour, the detachment rate exists but is small when the thickness TN of the nickel layer is 0.1 μm to 1 μm. In the case where the thickness TN is 1 μm, the detachment rate becomes the lowest value. In the case where the thickness TN is equal to or more than 1 μm, the detachment rate increases as the thickness TN becomes thick.

It can be seen from the graph of FIG. 8, when the formation speed of the nickel layer is from 6.9 μm/hour to 12.2 μm/hour and the thickness TN of the nickel layer is 1.0 μm to 3.0 μm, the detachment rate becomes 0%. This is a preferred condition. Further, it is considered when the formation speed of the nickel layer is from 5 μm/hour to 15 m/hour, at least the detachment rate becomes 0% or a value close to 0%. This is a preferred condition.

Returning to FIG. 4, in step S404, a part of the electroless plating film 153 is removed. The electroless plating film 153 is removed by a method such as the following. A laser is irradiated to the electroless plating film 153. Or, the electroless plating film 153 is chipped off by dicing.

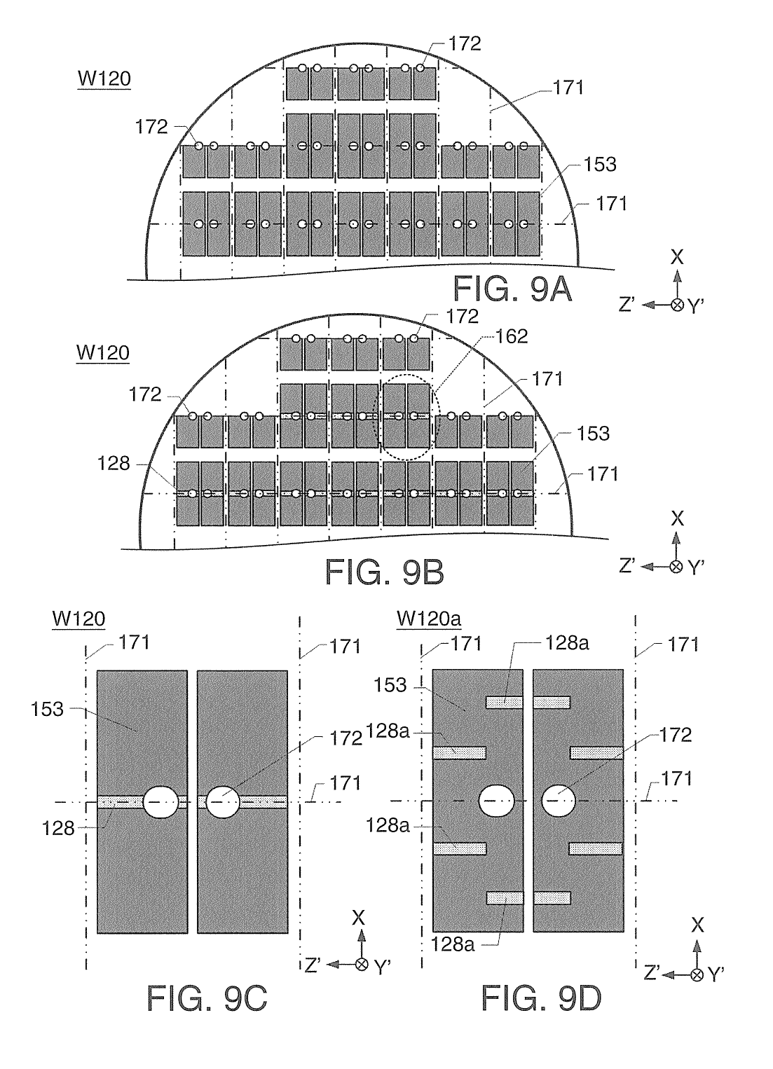

FIG. 9A is a partial plan view of the surface at the −Y′-axis side of the base wafer W120 where the electroless plating film 153 is formed. FIG. 9A illustrates a state before step S404. A plurality of electroless plating films 153 is formed on the surface at the −Y′-axis side of the base wafer W120. One electroless plating film 153 is formed long in the X-axis direction across the scribe line 171 that extends in the Z′-axis direction.

FIG. 9B is a partial plan view of a surface at the −Y′-axis side of the base wafer W120 from which a part of the electroless plating film 153 is removed. FIG. 9B illustrates a state after step S404. In the base wafer W120 illustrated in FIG. 9B, the electroless plating film 153, which extends in the X-axis direction, is removed such that the electroless plating film 153 is divided along the scribe line 171, which extends at the center of the electroless plating film 153 across the Z′-axis. At the region where this electroless plating film 153 is removed, the trace 128 remains after the electroless plating film 153 is removed. At the removal of the electroless plating film 153, the first metal film 151, which is formed below the electroless plating film 153, may be removed.

FIG. 9C is an enlarged plan view of the portion enclosed by a dotted line 162 of FIG. 9B. One electroless plating film 153 is formed long in the X-axis direction. The scribe line 171 extending in the Z′-axis direction is formed across the center of the electroless plating film 153. That is, the trace 128, which is a trace formed along the Z′-axis direction and from which the electroless plating film 153 is removed, is formed such that the length of the electroless plating film 153 in the X-axis direction becomes approximately half.

The electroless plating film 153 applies stress proportionate to its formation length to the base wafer W120. In the base wafer W120, the electroless plating film 153 is formed long in the X-axis direction. Therefore, strong stress is applied to the base wafer W120 in the X-axis direction. This warps the surface at the −Y-axis side of the base wafer W120 to hollow. The trace 128, from which the electroless plating film 153 is removed, is formed across the center of one electroless plating film 153. Accordingly, the electroless plating film 153 becomes short in the X-axis direction, and stress applied to the base wafer W120 is reduced.

In step S405, the lid wafer W110 and the base wafer W120 are diced. The lid wafer W110 and the base wafer W120 are diced at the scribe line 171 by a method such as dicing. Step S405 is a dicing process.

Stress applied to the base wafer W120 by the electroless plating film 153 changes by dicing the wafer in step S404, causing distortion in the piezoelectric device. The mounting terminal or the electroless plating film 153 formed on the piezoelectric device may be detached by this distortion. With the piezoelectric device 100, stress generated in the wafer is reduced by removing a part of the electroless plating film 153 before dicing the wafer. Accordingly, distortion in the piezoelectric device after the wafer is diced is suppressed small. This suppresses detachment of the mounting terminal or the electroless plating film 153.

With the piezoelectric device 100, the detachment rate of the electroless plating film 153 can be reduced by the following. The formation speed of the nickel layer of the electroless plating film 153 is set to 5 μm/hour to 15 μm/hour, and the thickness TN of the nickel layer is set to 1 μm to 3 μm.

### Modification of the Piezoelectric Device 100

FIG. 9D is an enlarged plan view of the surface at the −Y′-axis side of a base wafer W120a. In step S404, the electroless plating film 153 formed on the region other than the scribe line 171 may be removed. In the base wafer W120a, the electroless plating film 153 formed on the region other than the scribe line 171 is removed. The electroless plating film 153 illustrated in FIG. 9D is formed long in the X-axis direction. Accordingly, a trace 128a, which is illustrated in FIG. 9D, from which the electroless plating film 153 is removed, is formed such that the length of the electroless plating film 153 in the X-axis direction becomes short. This reduces stress in the X-axis direction applied by the electroless plating film 153.

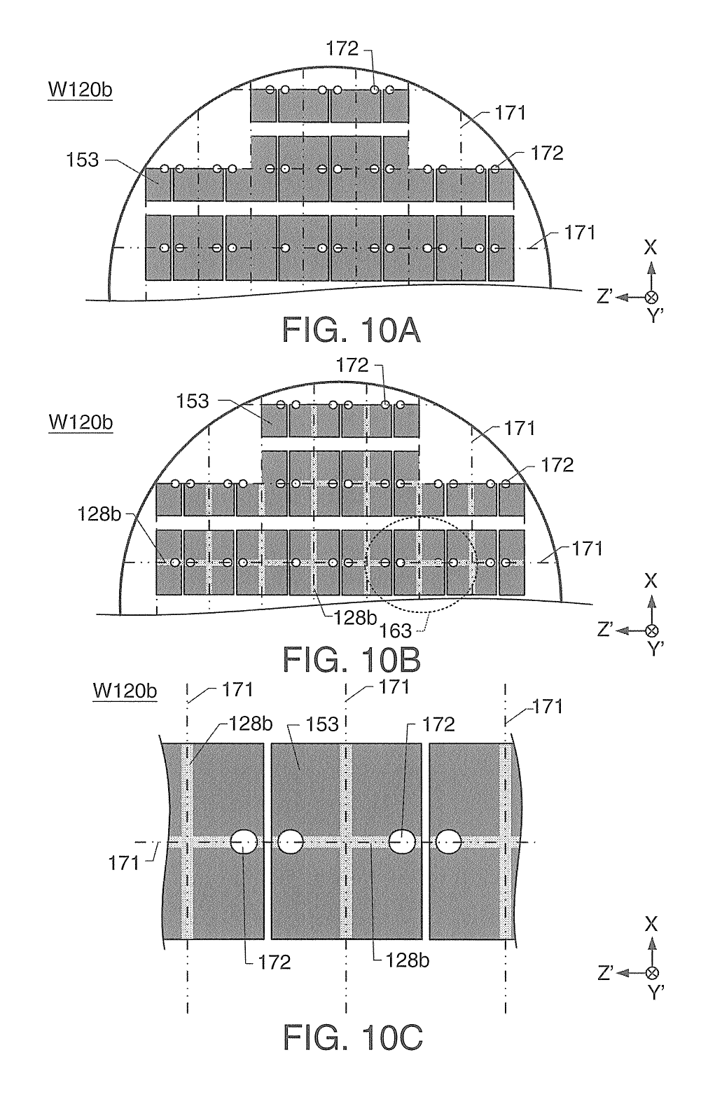

FIG. 10A is a partial plan view of the surface at the −Y′-axis side of a base wafer W120b before the electroless plating film 153 is removed. In the base wafer W120b, the electroless plating film 153 is formed long in the X-axis direction and the Z′-axis direction. A piezoelectric device tends to be downsized, and therefore the area of a mounting terminal becomes small. Accordingly, a line width of a mask to form the first metal film 151 becomes narrow, and there is a problem that the mask is easily damaged. In the base wafer W120b illustrated in FIG. 10A, the area of the mounting terminal is formed large. This eliminates a part where the line width of the mask becomes narrow and restricts damage in the mask. In the base wafer W120b, the electroless plating film 153 is formed to be divided in the X-axis direction and the Z′-axis direction by the scribe line 171 extending in the X-axis direction and the scribe line 171 extending in the Z′-axis direction, respectively. FIG. 10A illustrates the base wafer W120b in a state after the electroless plating film 153 is formed in step S403 in FIG. 4.

FIG. 10B is a partial plan view of the surface at the −Y′-axis side of the base wafer W120b after the electroless plating film 153 is removed. In the base wafer W120b, the electroless plating film 153 is formed long in the X-axis direction and the Z′-axis direction. A trace 128b, from which the electroless plating film 153 formed on the base wafer W120b is removed, is formed along the scribe lines 171, which extend in the X-axis direction and the Z′-axis direction.

FIG. 10C is an enlarged plan view of the portion enclosed by a dotted line 163 of FIG. 10B. The trace 128b, which is a trace from which the electroless plating film 153 formed on the base wafer W120b is removed, extends in the X-axis direction and the Z′-axis direction. The trace 128b is formed such that the electroless plating film 153 is divided in the Z′-axis direction and the X-axis direction. Accordingly, stress generated by the electroless plating film 153 is reduced in the X-axis direction and the Z′-axis direction.

### Second Embodiment

A piezoelectric vibrating piece that includes a framing portion surrounding a peripheral area of a vibrator may be employed as a piezoelectric vibrating piece. A description will be given of a piezoelectric device 200 where a piezoelectric vibrating piece with a framing portion is employed. The embodiment will now be described wherein like reference numerals designate corresponding or identical elements throughout the embodiments.

### Constitution of the Piezoelectric Device 200

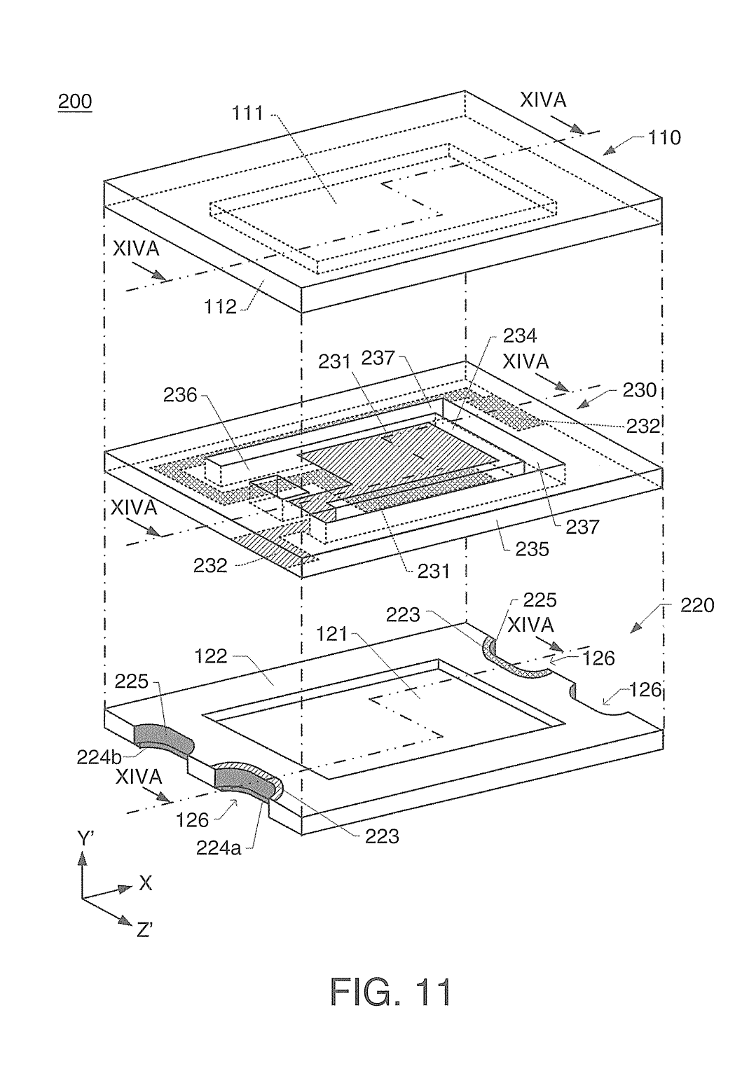

FIG. 11 is an exploded perspective view of the piezoelectric device 200. The piezoelectric device 200 includes a lid plate 110, a base plate 220, and a piezoelectric vibrating piece 230. With the piezoelectric device 200, similarly to the first Embodiment, an AT-cut quartz-crystal vibrating piece is employed for the piezoelectric vibrating piece 230.

The piezoelectric vibrating piece 230 includes a vibrator 234, a framing portion 235, and a connecting portion 236. The vibrator 234 vibrates at a predetermined frequency and has a rectangular shape. The framing portion 235 is formed to surround a peripheral area of the vibrator 234. The connecting portion 236 connects the vibrator 234 and the framing portion 235. Between the vibrator 234 and the framing portion 235, a through groove 237 that passes through the piezoelectric vibrating piece 230 in the Y′-axis direction is formed. The vibrator 234 and the framing portion 235 do not directly contact one another. The vibrator 234 and the framing portion 235 are connected together via the connecting portion 236 connected at the −X-axis side and the +Z′-axis side, and at the −X-axis side and the −Z′-axis side of the vibrator 234. Further, excitation electrodes 231 are formed on surfaces of the +Y′-axis side and the −Y′-axis side of the vibrator 234. An extraction electrode 232 is extracted from each excitation electrode 231 to the framing portion 235. The extraction electrode 232 is extracted from the excitation electrode 231, which is formed on the surface at the +Y′-axis side of the vibrator 234. The extraction electrode 232 is extracted to the −X-axis side on the surface at the −Y′-axis side of the framing portion 235 via the connecting portion 236 at the +Z′-axis side. The extraction electrode 232 is extracted from the excitation electrode 231, which is formed on the surface at the −Y′-axis side of vibrator 234. The extraction electrode 232 is extracted to the −X-axis side of the framing portion 235 via the connecting portion 236 at the −Z′-axis side, and is further extracted up to the +X-axis side and the −Z′-axis side of the framing portion 235.

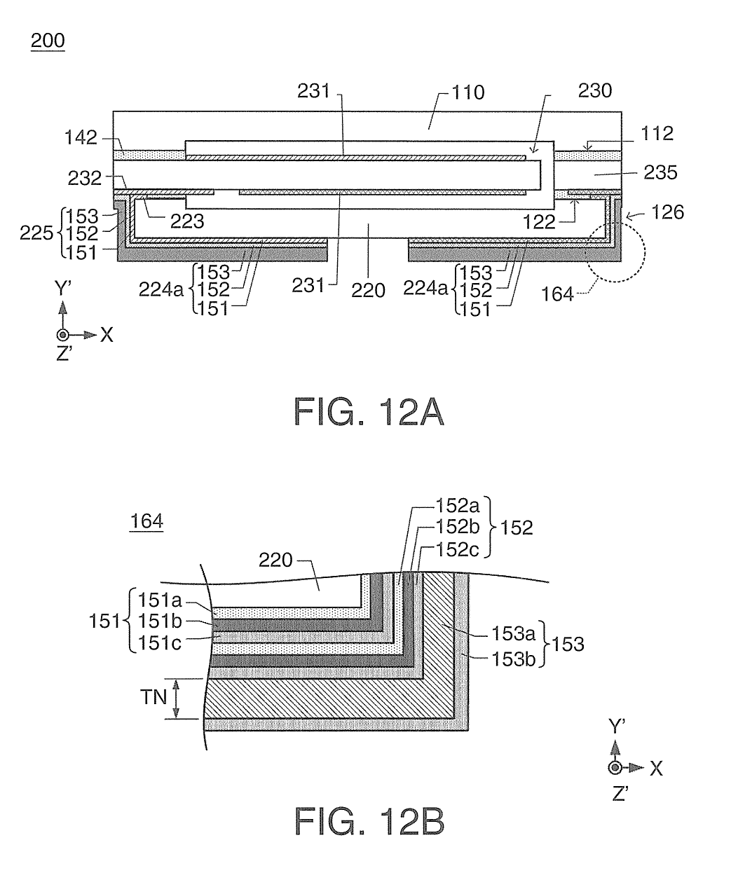

A bonding surface 122 is formed at the peripheral area of the surface at the +Y′-axis side of the base plate 220. The bonding surface 122 is to be bonded to the lid plate 110 via a sealing material 142 (see FIG. 12A). The base plate 220 includes a depressed portion 121 at he center of the surface at the +Y′-axis side. The depressed portion 121 is depressed from the bonding surface 122 in the −Y′-axis direction. A castellation 126 is formed at a side surface of the base plate 220. A side surface electrode 225 is formed at a side surface of the castellation 126. Further, a connecting electrode 223 is formed at the peripheral area of the castellation 126 of the bonding surface 122. A hot terminal 224a and a grounding terminal 224b are formed on the surface at the −Y′-axis side of the base plate 220. The shape of the surface at −Y′-axis side of the base plate 220 is the same as the shape illustrated in FIG. 3B. The shapes of the hot terminal 224a and the grounding terminal 224b are formed same as the shapes of the hot terminal 124a and the grounding terminal 124b. The connecting electrode 223 is formed at the peripheral area of the castellation 126 of the bonding surface 122. The connecting electrode 223 electrically connects to the hot terminal 224a via the side surface electrode 225 formed on the castellation 126.

FIG. 12A is a cross-sectional view taken along the line XIVA-XIVA of FIG. 11. The piezoelectric device 200 is formed by bonding the bonding surface 112 of the lid plate 110 and the surface at the +Y′-axis side of the framing portion 235 together via the sealing material 142. The bonding surface 122 of the base plate 220 and the surface at the −Y′-axis side of the framing portion 235 are bonded together via the sealing material 142. The extraction electrode 232 and the connecting electrode 223 are electrically bonded together at the bonding of the piezoelectric vibrating piece 230 and the base plate 220. This electrically connects the excitation electrode 231 to the hot terminal 224a. The hot terminal 224a and the grounding terminal 224b, which are formed on the base plate 220, are formed of the first metal film 151, the second metal film 152, and the electroless plating film 153. Similarity to the hot terminal 124a and the grounding terminal 124b illustrated in FIG. 2A and FIG. 3B, in the hot terminal 224a and the grounding terminal 224b, the electroless plating films 153 at regions in contact with sides at the +X-axis side and the −X-axis side of the base plate 220 are chipped off.

FIG. 12B is an enlarged view of the portion enclosed by a dotted line 164 of FIG. 12A. FIG. 12B illustrates an enlarged cross-sectional view of the hot terminal 224a. The first metal film 151 is formed of three layers: a first layer 151a, a second layer 151b, and a third layer 151c. As illustrated in FIG. 2B, the first layer 151a is made of a chrome (Cr), the second layer 151b is made of a nickel tungsten (Ni—W), a platinum (Pt), or similar material, and the third layer 151c is made of a gold (Au).

The second metal film 152 includes a first layer 152a , a second layer 152b, and a third layer 152c. The first layer 152a is formed on the surface of the first metal film 151. The second layer 152b is formed on the surface of the first layer 152a . The third layer 152c is formed on the surface of the second layer 152b. The first layer 152a , the second layer 152b, and the third layer 152c are formed of the same constitution as the first layer 151a, the second layer 151b, and the third layer 151c of the first metal film 151, respectively. In short, the second metal film 152 is formed of the same constitution as the first metal film 151.

The electroless plating film 153 is formed of the first layer 153a and the second layer 153b. The first layer 153a is formed on a surface of the second metal film 152. The second layer 153b is formed on a surface of the first layer 153a. The first layer 153a is a nickel (Ni) layer and has the thickness TN of 1 μm to 3 μm. To ensure connection of a mounting terminals 224a and 224b and a solder or similar material, the second layer 153b made of a gold (Au) is formed on a surface of the first layer 153a.

### Fabrication Method of the Piezoelectric Device 200

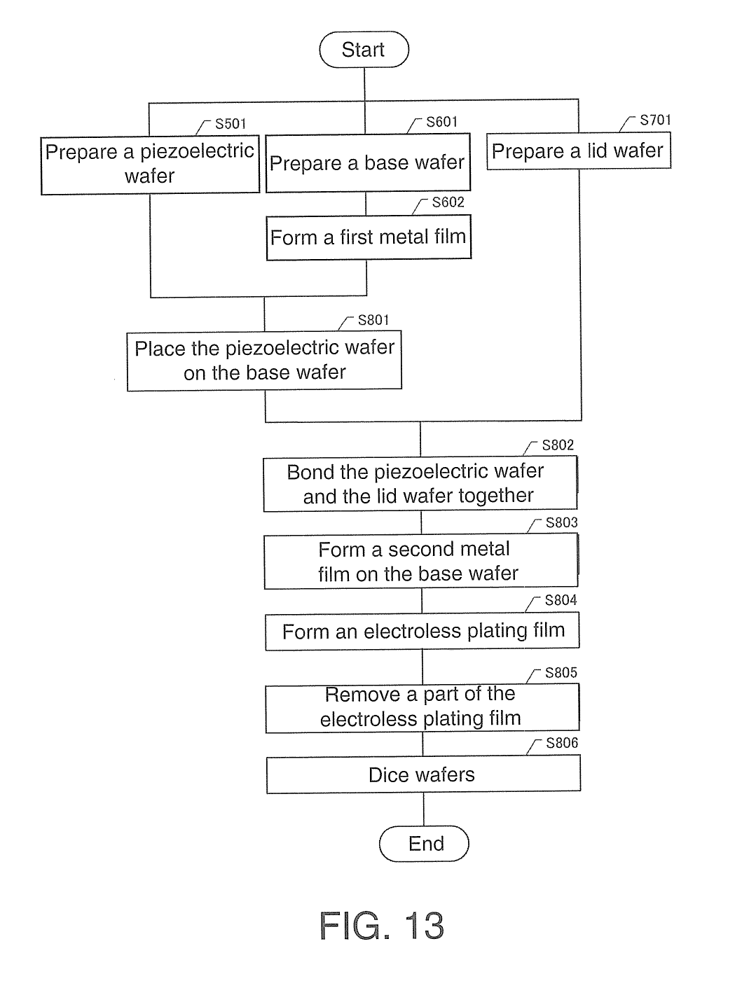

FIG. 13 is a flowchart illustrating a method for fabricating the piezoelectric device 200. A description will be given of the method for fabricating the piezoelectric device 200 following the flowchart of FIG. 13.

In step S501, a piezoelectric wafer W230 is prepared. A plurality of piezoelectric vibrating pieces 230 is formed on the piezoelectric wafer W230. Step S501 is a process for preparing a piezoelectric wafer.

In step S601, a base wafer W220 is prepared. Step S601 is a process for preparing the base wafer W220. A plurality of base plates 220 is formed on the base wafer W220. The base wafer W220 employs a material such as a crystal or a glass as the base material. In the base wafer W220, the depressed portion 121 and the through hole 172, which becomes the castellation 126 by dicing the wafer, are formed by etching.

In step S602, the first metal film 151 is formed on the base wafer W220. As illustrated in FIG. 12A, the first metal film 151 forms the side surface electrode 225, the hot terminal 224a, a part of the grounding terminal 224b, and the connecting electrode 223. Step S602 is a process for forming a first metal film.

In step S701, the lid wafer W110 is prepared. Step S701 is a process for preparing the lid wafer W110. A plurality of lid plates 110 is formed on the lid wafer W110. The depressed portion 111 is formed on the surface at the −Y′-axis side of each lid plate 110.

In step S801, the piezoelectric wafer W230 is placed on the base wafer W220. Step S801 is a placement process where the base wafer W220 and the piezoelectric wafer W230 are bonded together such that each piezoelectric vibrating piece 230 of the piezoelectric wafer W230 is placed corresponding to the surface at the +Y′-axis side of each base plate 220 of the base wafer W220. In this placement process, the bonding surface 122 of the base wafer W220 is bonded on the surface at the −Y′-axis side of the framing portion 235, which is formed on the piezoelectric wafer W230, via the sealing material 142.

In step S802, the piezoelectric wafer W230 and the lid wafer W110 are bonded together. Step S802 is a bonding process where the lid wafer W110 is bonded to the surface at the +Y′-axis side of the piezoelectric wafer W230 via the sealing material 142, so as to seal the vibrator 234 of the piezoelectric vibrating piece 230.

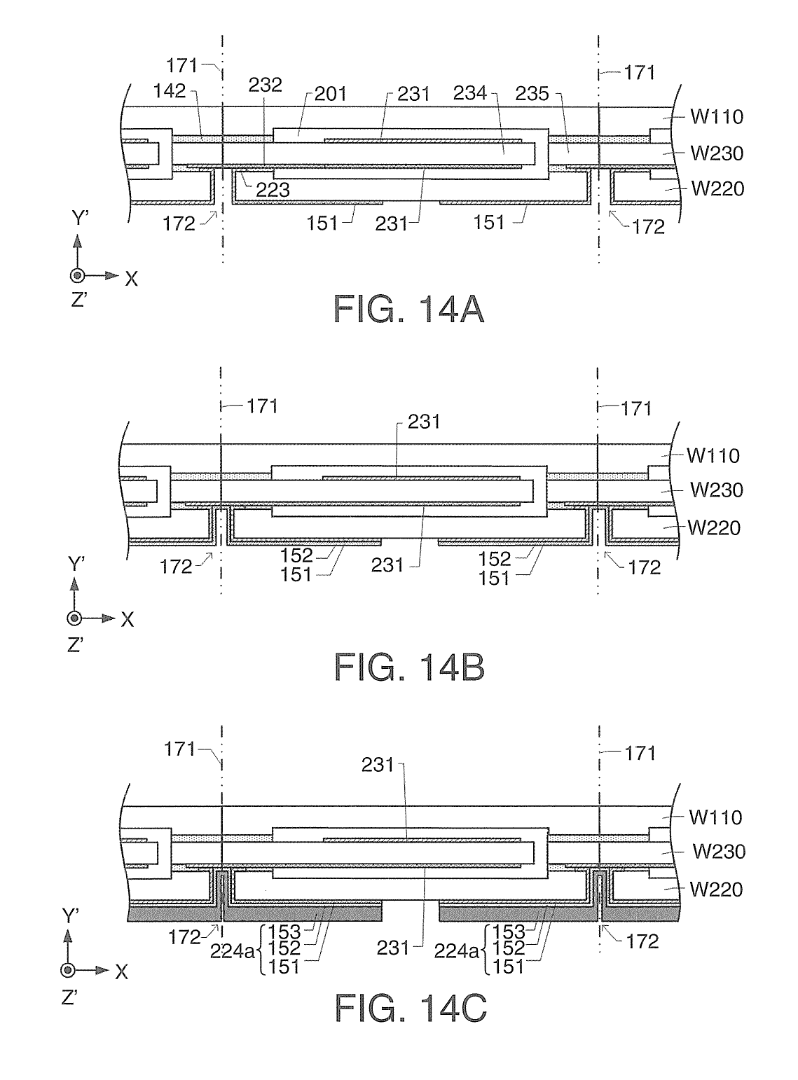

FIG. 14A is a partial cross-sectional view of the piezoelectric wafer W230, the lid wafer W110, and the base wafer W220. FIG. 14A is a cross-sectional view including a cross section taken along the line XIVA-XIVA of FIG. 11. The base wafer W220 is bonded to the surface at the −Y′-axis side of the framing portion 235 of the piezoelectric wafer W230 via the sealing material 142. The connecting electrode 223 electrically connects to the extraction electrode 232. The lid wafer W110 is bonded to the surface at the +Y′-axis side of the framing portion 235 of the piezoelectric wafer W230 via the sealing material 142. This forms a cavity 201, and the vibrator 234 is sealed into this cavity 201.

In step S803, the second metal film 152 is formed on the base wafer W220. Step S803 is a process for forming a second metal film. The second metal film 152 is formed on the surface of the first metal film 151, which is formed on the surface at the −Y′-axis side and the through hole 172 of the base wafer W220.

FIG. 14B is a partial cross-sectional view of the piezoelectric wafer W230, the lid wafer W110, and the base wafer W220 where the second metal film 152 is formed.

In step S804, the electroless plating film 153 is formed on the base wafer W220. The electroless plating film 153 is formed on the surface of the second metal film 152 formed on the base wafer W220. The surface at the −Y′-axis side of the base wafer W220 where the electroless plating film 153 is formed is shaped similarity to the surface at the −Y′-axis side of the base wafer W120 illustrated in FIG. 9A. Step S804 is a process of electroless plating.

FIG. 14C is a partial cross-sectional view of the piezoelectric wafer W230, the lid wafer W110, and the base wafer W220 where the electroless plating film 153 is formed. The electroless plating film 153, which is formed on the piezoelectric wafer W230 and the base wafer W220, is formed on the surface of the second metal film 152. A nickel layer, which forms the electroless plating film 153, is formed to have the thickness TN of 1 μm to 3 μm at a deposition rate of 5 μm/hour to 15 μm/hour.

In step S805, a part of the electroless plating film 153 is removed. Similarity to FIGS. 9B and 9C, the electroless plating film 153 that is formed on the scribe line 171 extending in the Z′-axis direction is removed. Step S806 is a removal process where a part of the electroless plating film 153 is removed by laser or dicing.

In step S806, the base wafer W220, the lid wafer W110, and the piezoelectric wafer W230 are diced at the scribe line 171. Thus, individual piezoelectric devices 200 are formed. Step S806 is a dicing process.

In the piezoelectric device 200, similarity to the piezoelectric device 100, stress applied to the base wafer W220 is reduced by removing a part of the electroless plating film 153. In the dicing process, distortion of the piezoelectric device 200 is restricted by reduction of stress, preventing detachment of the mounting terminals 224a and 224b. In a piezoelectric device, an electroless plating film may not be formed due to contamination of the surface of the metal film, which becomes a foundation layer of the electroless plating film, or similar cause. With the piezoelectric device 200, formation of the second metal film 152, which becomes a foundation layer, immediately before performing electroless plating suppresses influence by contamination of the foundation layer or similar cause to the minimum.

Representative embodiments are described in detail above; however, as will be evident to those skilled in the relevant art, this disclosure may be changed or modified in various ways within its technical scope.

For example, an oscillator may be embedded to the piezoelectric device, so as to form a piezoelectric oscillator. Additionally, the above-described embodiments disclose a case where the piezoelectric vibrating piece is an AT-cut quartz-crystal vibrating piece. A BT-cut quartz-crystal vibrating piece or similar member that similarly vibrates in the thickness-shear mode is similarly applicable. Further, the piezoelectric vibrating piece is basically applicable to a piezoelectric material that includes not only a quartz-crystal material but also lithium tantalite, lithium niobate, and piezoelectric ceramic.

Further, for example, in FIG. 9D, the first metal film 151 and the second metal film 152 are not formed at the portion of the trace 128a. Accordingly, the electroless plating film 153 may not be formed at the portion of the trace 128a. This case also allows reducing stress applied in the X-axis direction by the electroless plating film 153.

In the first aspect of the disclosure, the piezoelectric device according to a second aspect is configured as follows. The trace from which a part of the electroless plating film is removed extends in a direction where a short side or a long side of the base plate extends.

In the second aspect of the disclosure, the piezoelectric device according to a third aspect is configured as follows. The trace from which the part of the electroless plating film is removed is in contact with at least a part of the short side or the long side of the base plate.

In the second aspect of the disclosure, the piezoelectric device according to a fourth aspect is configured as follows. The trace from which the part of the electroless plating film is removed extends from an outer periphery of the mounting terminal to an inside of the mounting terminal.

A method for fabricating a piezoelectric device according to a fifth aspect includes preparing a plurality of piezoelectric vibrating pieces, preparing a base wafer, preparing a lid wafer, a first metal film forming, placing, bonding the lid wafer, plating, removing, and dicing. The base wafer includes a plurality of rectangular base plates. The lid wafer includes a plurality of lid plates. The first metal film forming forms first metal films on predetermined regions on both principal surfaces of the base wafer. The placing places the plurality of piezoelectric vibrating pieces on one principal surface of the base wafer. The bonding bonds the lid wafer on one principal surface of the base wafer to seal the piezoelectric vibrating piece. The plating plates an electroless plating film on a surface of the metal film formed on another principal surface of the base wafer by electroless plating. The removing removes a part of the electroless plating film by laser or dicing. The dicing dices the base wafer and the lid wafer including the boundary between the adjacent base plates. The metal film formed on the other principal surface of the base wafer is disposed across at least a part of the boundary.

A method for fabricating the piezoelectric device according to a sixth aspect includes preparing a piezoelectric wafer, preparing a base wafer, preparing a lid wafer, a first metal film forming, bonding the base wafer and the piezoelectric wafer, bonding the lid wafer, plating, removing, and dicing. The piezoelectric wafer includes a plurality of piezoelectric vibrating pieces. The piezoelectric vibrating piece includes a vibrator, a framing portion, and a connecting portion. The vibrator vibrates at a predetermined vibration frequency. The framing portion surrounds the vibrator. The connecting portion connects the vibrator and the framing portion. The base wafer includes a plurality of rectangular base plates. The lid wafer includes a plurality of lid plates. The first metal film forming forms first metal films on predetermined regions on both principal surfaces of the base wafer. The base wafer and the piezoelectric wafer are bonded such that the piezoelectric vibrating pieces are placed on one principal surfaces of the respective base plates. The lid wafer is bonded on the piezoelectric wafer to seal the vibrator. The plating plates an electroless plating film on a surface of the metal film formed on another principal surface of the base wafer by electroless plating. The removing removes a part of the electroless plating film by laser or dicing. The dicing dices the base wafer and the lid wafer including the boundary between the adjacent base plates. The metal film formed on the other principal surface of the base wafer is disposed across at least a part of the boundary.

In the fifth aspect and the sixth aspect of the disclosure, the method for fabricating the piezoelectric device according to a seventh aspect further includes: removing a part of the electroless plating film in a direction where the boundary between the adjacent base plates extends.

In the seventh aspect of the disclosure, the method for fabricating the piezoelectric device according to an eighth aspect further includes: removing a part of the electroless plating film disposed on at least a part of the boundary between the adjacent base plates.

In the seventh aspect of the disclosure, the method for fabricating the piezoelectric device according to a ninth aspect further includes: removing the part of the electroless plating film from an outer periphery of the mounting terminal toward an inside of the mounting terminal.

In the fifth aspect to the ninth aspect of the disclosure, the method for fabricating the piezoelectric device according to a tenth aspect further includes: a second metal film forming process that forms a second metal film on a surface of the metal film formed on the other principle surface of the base wafer, after the one principal surface bonding and before the electroless plating.

In the fifth aspect to the tenth aspect of the disclosure, the method for fabricating the piezoelectric device according to an eleventh aspect is configured as follows. The metal film includes a chromium layer, a nickel tungsten layer, and a gold layer. The nickel tungsten layer is formed on a surface of the chromium layer. The gold layer is formed on a surface of the nickel tungsten layer.

In the fifth aspect to the tenth aspect of the disclosure, the method for fabricating the piezoelectric device according to a twelfth aspect is configured as follows. The metal film includes a chromium layer, a platinum layer, and a gold layer. The platinum layer is formed on a surface of the chromium layer. The gold layer is formed on a surface of the platinum layer.

In the fifth aspect to the twelfth aspect of the disclosure, the method for fabricating the piezoelectric device according to a thirteenth aspect is configured as follows. The electroless plating film includes a nickel layer. The nickel layer is formed at a deposition rate of 5 μm/hour to 15 μm/hour.

A piezoelectric device according to a fourteenth aspect is a surface mount type piezoelectric device. The surface mount type piezoelectric device includes a piezoelectric vibrating piece, a base plate in a rectangular shape, and a lid plate. The piezoelectric vibrating piece includes a vibrator vibrating at a predetermined vibration frequency. The base plate has one principal surface where the piezoelectric vibrating piece being to be placed. The lid plate seals the vibrator. The base plate has another principal surface that includes a pair of mounting terminals to mount the piezoelectric device. The mounting terminal includes a region formed of a metal film and an electroless plating film. The electroless plating film is formed on a surface of the metal film. The mounting terminal includes: a first region that includes the metal film and the electroless plating film formed on the metal film; and a second region where the metal film and the electroless plating film are not formed, and the second region is sandwiched by the first region that includes the metal film and the electroless plating film. The second region is parallel to a short side or a long side of the base plate. The second region extends from an outer periphery of the mounting terminal toward an inside of the mounting terminal.

With the piezoelectric device and the method for fabricating the piezoelectric device according to the embodiments, detachment of an electrode formed by electroless plating can be avoided.

The principles, preferred embodiment and mode of operation of the present disclosure have been described in the foregoing specification. However, the disclosure which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present disclosure. Accordingly, it is expressly intended that all such variations, changes and equivalents which fall within the spirit and scope of the present disclosure as defined in the claims, be embraced thereby.

What is claimed is:

1. A surface mount type piezoelectric device, comprising:
a piezoelectric vibrating piece that includes a vibrator vibrating at a predetermined vibration frequency;
a base plate in a rectangular shape that has one principal surface where the piezoelectric vibrating piece being to be placed; and
a lid plate that seals the vibrator, wherein
the other principal surface of the base plate includes a pair of mounting terminals to mount the piezoelectric device, the pair of mounting terminals including a metal film and an electroless plating film, the electroless plating film being formed on a surface of the metal film, and
the mounting terminal includes a trace from which a part of the electroless plating film is removed by laser or dicing.

2. The piezoelectric device according to claim 1, wherein
the trace from which a part of the electroless plating film is removed extends in a direction where a short side or a long side of the base plate extends.

3. The piezoelectric device according to claim 2, wherein
the trace from which the part of the electroless plating film is removed is in contact with at least a part of the short side or the long side of the base plate.

4. The piezoelectric device according to claim 2, wherein
the trace from which the part of the electroless plating film is removed extends from an outer periphery of the mounting terminal to an inside of the mounting terminal.

5. A method for fabricating a piezoelectric device, comprising:
preparing a piezoelectric wafer that includes a plurality of piezoelectric vibrating pieces, the piezoelectric vibrating piece including a vibrator, a framing portion, and a connecting portion, the vibrator vibrating at a predetermined vibration frequency, the framing portion surrounding the vibrator, the connecting portion connecting the vibrator and the framing portion;
preparing a base wafer that includes a plurality of rectangular base plates;
preparing a lid wafer that includes a plurality of lid plates;
forming first metal films on predetermined regions on both principal surfaces of the base wafer;
bonding the base wafer and the piezoelectric wafer such that the piezoelectric vibrating pieces are placed on one principal surfaces of the respective base plates;
bonding the lid wafer on the piezoelectric wafer to seal the vibrator;
plating an electroless plating film on a surface of the metal film formed on another principal surface of the base wafer by electroless plating;
removing a part of the electroless plating film by laser or dicing; and
dicing the base wafer and the lid wafer including the boundary between the adjacent base plates, wherein
the metal film formed on the other principal surface of the base wafer is disposed across at least a part of the boundary.

6. The method for fabricating the piezoelectric device according to claim 5, further comprising:
removing a part of the electroless plating film in a direction where the boundary between the adjacent base plates extends.

7. The method for fabricating the piezoelectric device according to claim 6, further comprising:
removing a part of the electroless plating film disposed on at least a part of the boundary between the adjacent base plates.

8. The method for fabricating the piezoelectric device according to claim 6, further comprising:
removing the part of the electroless plating film from an outer periphery of the mounting terminal toward an inside of the mounting terminal.

9. The method for fabricating the piezoelectric device according to claim 5, further comprising:
forming a second metal film on a surface of the metal film formed on the other principle surface of the base wafer, after the one principal surface bonding and before the electroless plating.

10. The method for fabricating the piezoelectric device according to claim 5, wherein
the metal film includes a chromium layer, a nickel tungsten layer, and a gold layer,
the nickel tungsten layer is formed on a surface of the chromium layer, and
the gold layer is formed on a surface of the nickel tungsten layer.

11. The method for fabricating the piezoelectric device according to claim 5, wherein
the metal film includes a chromium layer, a platinum layer, and a gold layer,
the platinum layer s formed on a surface of the chromium layer, and
the gold layer is formed on a surface of the platinum layer.

12. The method for fabricating the piezoelectric device according to claim 5, wherein
the electroless plating film includes a nickel layer, and
the nickel layer is formed at a deposition rate of 5 μm/hour to 15 μm/hour.

13. A surface mount type piezoelectric device, comprising:
a piezoelectric vibrating piece that includes a vibrator vibrating at a predetermined vibration frequency;
a base plate in a rectangular shape that has one principal surface where the piezoelectric vibrating piece being to be placed; and
a lid plate that seals the vibrator, wherein
the base plate has another principal surface that includes a pair of mounting terminals to mount the piezoelectric device,
the mounting terminal includes:
a first region formed of a metal film and an electroless plating film, the electroless plating film being formed on a surface of the metal film, and
a second region where the metal film and the electroless plating film are not formed, and the second region is sandwiched by the first region that includes the metal film and the electroless plating film, the second region being parallel to a short side or a long side of the base plate, the second region extending from an outer periphery of the mounting terminal toward an inside of the mounting terminal.
